(19) United States
(12) Patent Application Publication
(10) Pub. No.: US 2025/0112063 A1
(43) Pub. Date: Apr. 3, 2025

(54) SUBSTRATE PROCESSING METHOD, METHOD OF MANUFACTURING SEMICONDUCTOR DEVICE, RECORDING MEDIUM, AND SUBSTRATE PROCESSING APPARATUS

(71) Applicant: KOKUSAI ELECTRIC CORPORATION, Tokyo (JP)

(72) Inventors: Kimihiko NAKATANI, Toyama-shi (JP); Shoma MIYATA, Toyama-shi (JP); Takayuki WASEDA, Toyama-shi (JP)

(73) Assignee: KOKUSAI ELECTRIC CORPORATION, Tokyo (JP)

(21) Appl. No.: 18/887,519

(22) Filed: Sep. 17, 2024

(30) Foreign Application Priority Data
Oct. 3, 2023 (JP) 2023-172049

(51) Int. Cl. H01L 21/67

(52) U.S. Cl. CPC H01L 21/67248

(57) ABSTRACT

There is provided a technique that includes: (a) regulating a temperature in a process chamber configured to accommodate a plurality of substrates so that a temperature distribution in an arrangement direction of the substrates in the process chamber becomes a first distribution in which at least a portion of an inside of the process chamber becomes a first temperature; (b) loading the substrates into the process chamber in a state where the temperature distribution in the arrangement direction is the first distribution; (c) after (b), regulating the temperature in the process chamber so that the temperature distribution in the arrangement direction becomes a second distribution in which at least a portion of the inside of the process chamber becomes a second temperature different from the first temperature; and (d) after (c), processing the substrates in a state where the temperature distribution in the arrangement direction is the second distribution.

### CROSS-REFERENCE TO RELATED APPLICATION

This application is based upon and claims the benefit of priority from Japanese Patent Application No. 2023-172049, filed on Oct. 3, 2023, the entire contents of which are incorporated herein by reference.

### TECHNICAL FIELD

The present disclosure relates to a substrate processing method, a method of manufacturing a semiconductor device, a recording medium, and a substrate processing apparatus.

### BACKGROUND OF THE INVENTION

In the related art, as a process of manufacturing a semiconductor device, a process of loading a substrate into a process chamber may be performed.

By loading the substrate into the process chamber, a temperature distribution in the process chamber may be changed to a temperature distribution different from a temperature distribution (target temperature distribution) used when processing the substrate. In this case, in order to converge the changed temperature distribution to the target temperature distribution, a temperature in the process chamber may be regulated using a temperature regulating means such as a heater or the like. However, it may take time to converge the changed temperature distribution to the target temperature distribution.

### SUMMARY OF THE INVENTION

Some embodiments of the present disclosure provide a technique capable of shortening a time required for converging a temperature distribution in a process chamber, which fluctuates when loading a substrate into the process chamber, to a target temperature distribution, thereby improving a throughput of substrate processing.

According to embodiments of the present disclosure, there is provided a technique that includes: (a) regulating a temperature in a process chamber configured to accommodate a plurality of substrates so that a temperature distribution in an arrangement direction of the substrates in the process chamber becomes a first distribution in which at least a portion of an inside of the process chamber becomes a first temperature; (b) loading the substrates into the process chamber in a state in which the temperature distribution in the arrangement direction in the process chamber is the first distribution; (c) after (b), regulating the temperature in the process chamber so that the temperature distribution in the arrangement direction in the process chamber becomes a second distribution in which at least a portion of the inside of the process chamber becomes a second temperature different from the first temperature; and (d) after (c), processing the substrates in a state in which the temperature distribution in the arrangement direction in the process chamber is the second distribution.

### BRIEF DESCRIPTION OF DRAWINGS

The accompanying drawings, which are incorporated in and constitute a part of the specification, illustrate embodiments of the present disclosure.

FIG. 1 is a schematic diagram of a vertical process furnace of a substrate processing apparatus suitably used in embodiments of the present disclosure, in which a portion of the process furnace is illustrated in a vertical cross-sectional view.

FIG. 2 is a schematic configuration diagram of a controller of the substrate processing apparatus suitably used in the embodiments of the present disclosure, in which a control system of the controller is illustrated in a block diagram.

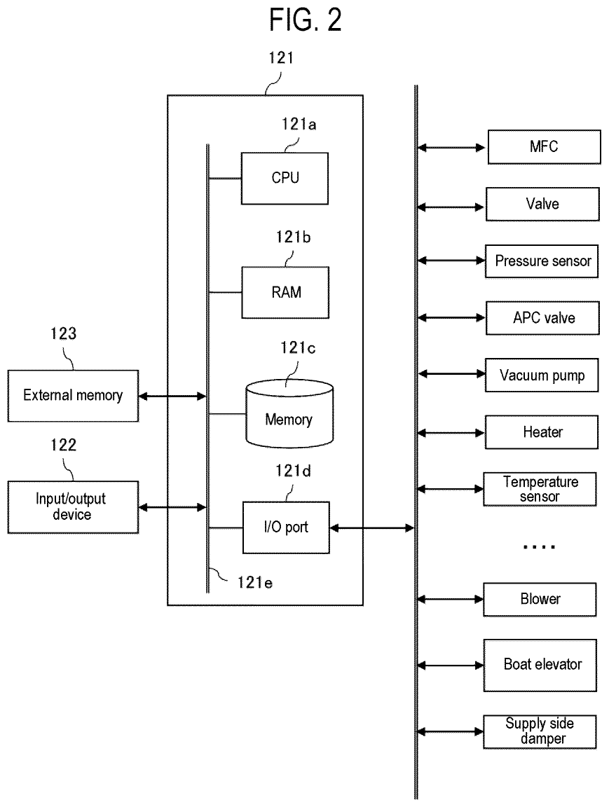

FIG. 3 is a diagram showing temperature changes in upper, central, and lower regions of a process chamber in the embodiments of the present disclosure.

FIG. 4 is a diagram showing temperature changes in the upper, central, and lower regions of the process chamber in modification 1.

FIG. 5 is a diagram showing temperature changes in the upper, central, and lower regions of the process chamber in modification 2.

### DETAILED DESCRIPTION

Reference is now made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### Embodiments of the Present Disclosure

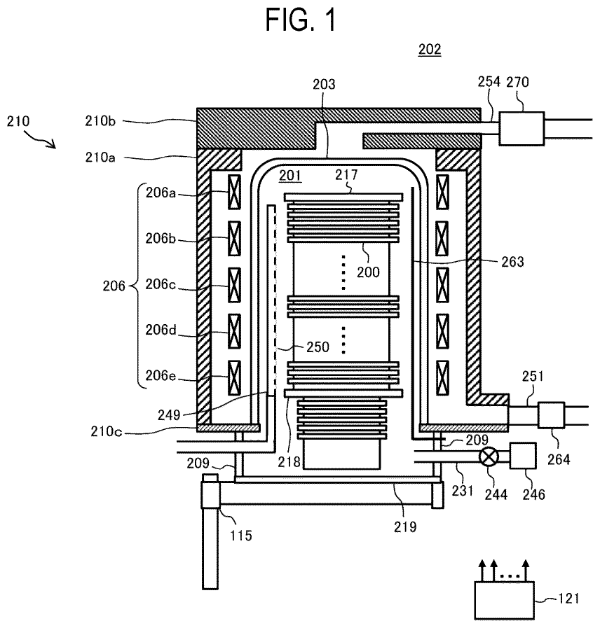

Embodiment of the present disclosure are described below mainly with reference to FIG. 1. All drawings used in the following description are schematic, and the dimensional relationships among respective elements, the proportions of respective elements, and the like shown in the drawings may not match the actual ones. Furthermore, the dimensional relationships among respective elements, the proportions of respective elements, and the like may not match among a plurality of drawings.

### (1) Configuration of Substrate Processing Apparatus

As shown in FIG. 1, the process furnace 202 includes a heater 206 as a temperature regulator (heating part). The heater 206 is formed in a cylindrical shape with open upper and lower ends, and is installed vertically. The heater 206 is composed of five zone heaters 206a, 206b, 206c, 206d and 206e arranged sequentially from the top along an arrangement direction of wafers 200 as substrates. These heaters 206a to 206e are configured such that a temperature of each zone may be controlled individually and independently. The heater 206 also functions as an activator (exciter) that activates (excites) a gas with heat. An outer wall 210 is provided outside the heater 206. The outer wall 210 includes a side wall 210a that covers a periphery of the heater 206, a ceiling 210b that covers an upper portion of the heater 206, and a bottom 210c that covers a lower portion of the heater 206.

An exhaust pipe 254, serving as an exhaust flow path for exhausting a cooling gas (cooling airflow) flowing between the reaction tube 203 and the outer wall 210, is provided in the outer wall 210 so as to penetrate the ceiling 210b. A blower 270, serving as a cooling gas exhaust device, is connected to the exhaust pipe 254. An exhaust side damper or an exhaust side shutter for regulating an exhaust flow rate may be provided on an upstream side of the blower 270 of the exhaust pipe 254.

Further, the outer wall 210 is provided with a supply pipe 251 for supplying a cooling gas between the reaction tube 203 and the outer wall 210. A supply side damper 264 is connected to the supply pipe 251 as a cooling gas flow rate regulator for regulating the supply flow rate of the cooling gas. Instead of the supply side damper 264, or together with the supply side damper 264, a supply side shutter may be connected to the supply pipe 251. The supply side damper 264 is capable of performing supply of the cooling gas and stopping the supply between the reaction tube 203 and the outer wall 210 by opening and closing a valve while the blower 270 is in operation. Furthermore, the supply side damper 264 is configured to be capable of adjusting an opening state of the valve while the blower 270 is operation, so that the flow rate of the cooling gas supplied between the reaction tube 203 and the outer wall 210 is regulated. The flow rate of the cooling gas may also be regulated by regulating a rotation speed of the blower 270.

A cooling gas exhauster is mainly composed of the exhaust pipe 254 and the blower 270. A cooling gas supplier is mainly composed of the supply pipe 251 and the supply side damper 264. A process chamber cooler (process chamber cooling system) as a cooling device is mainly composed of the cooling gas exhauster and the cooling gas supplier. The cooling gas flow rate regulator may include a blower 270 whose rotation speed is controllable, in addition to the supply side damper 264. The cooling airflow (cooling gas) taken in from the supply pipe 251 may be, for example, an air or an inert gas (e.g., a nitrogen gas or a rare gas) supplied from an inert gas supply source (not shown).

Inside the heater 206, a reaction tube 203 is disposed concentrically with the heater 206. The reaction tube 203 is made of a heat-resistant material such as quartz (SiO₂), silicon carbide (SiC) or the like and is formed in a cylindrical shape with a closed upper end and an opened lower end. A manifold 209 is disposed below the reaction tube 203 to be concentric with the reaction tube 203. The manifold 209 is made of a metal material such as stainless steel (SUS) or the like and is formed in a cylindrical shape with opened upper and lower ends. The upper end of the manifold 209 engages with the bottom 210c of the outer wall 210 and is configured to support the bottom 210c. The reaction tube 203 is installed vertically just like the heater 206. A process container (reaction container) is mainly composed of the reaction tube 203 and the manifold 209. A process chamber 201 is formed in a cylindrical hollow region of the process container. The process chamber 201 is configured to be capable of accommodating wafers the 200. The wafers 200 are processed in the process chamber 201.

A nozzle 249 as a gas introducer is provided in the process chamber 201 so as to penetrate a side wall of the manifold 209. A gas supply pipe (not shown) is connected to the nozzle 249. A processing gas supply source (not shown) or the like is connected to an upstream side of the gas supply pipe, which is a side opposite to a side connected to the nozzle 249, via an MFC (mass flow controller) (not shown), serving as a gas flow rate controller. In addition, an opening/closing valve (e.g., air valve) (not shown) is provided on at least one selected from the group of an upstream side and a downstream side of the MFC.

The manifold 209 is provided with an exhaust pipe 231 for exhausting an atmosphere in the process chamber 201. A vacuum pump 246 as a vacuum exhauster is connected to the exhaust pipe 231 via a pressure sensor (not shown) serving as a pressure detector for detecting a pressure in the process chamber 201 and an APC valve 244 serving as a pressure regulator. The APC valve 244 is configured to perform vacuum-exhaust of the process chamber 201 and stop the vacuum-exhaust by opening and closing the valve while the vacuum pump 246 is in operation. Further, the APC valve 244 is configured to regulate the pressure in the process chamber 201 by adjusting a valve opening state based on pressure information detected by the pressure sensor while the vacuum pump 246 is in operation. An exhaust system is mainly composed of the exhaust pipe 231, the APC valve 244, and the pressure sensor. The vacuum pump 246 may be included in the exhaust system.

A seal cap 219 is provided below the manifold 209 as a furnace port cover capable of airtightly closing a lower end opening of the manifold 209. The seal cap 219 is made of a metal material such as stainless steel or the like and is formed in a disk shape. The seal cap 219 is configured to be raised and lowered vertically by a boat elevator 115, which is installed outside the reaction tube 203 and serves as a lift for a boat 217 described later. The boat elevator 115 is configured as a transporter (transport mechanism) that raises and lowers the seal cap 219 to load and unload (transport) the wafers 200 into and out of the process chamber 201.

A region in the process container corresponding to the heater 206a (closed end side of the reaction tube 203) may be referred to as an upper region. A region in the process container corresponding to the heater 206b may be included in the upper region. A region in the process container corresponding to the heater 206e may be referred to as a lower region. A region below the heater 206e in the process container, for example, a region where the manifold 209 and an opening of the reaction tube 203 are located, may be included in the lower region. A region in the process container corresponding to the heater 206d may be included in the lower region. Further, a region in the process container corresponding to the heater 206c may be referred to as a central region. A region in the process container corresponding to at least one selected from the group of the heaters 206b and 206d may be included in the central region.

The boat 217 as a substrate transporter is configured to support a plurality of wafers 200, for example, 25 to 200 wafers, in such a state that the wafers are arranged in a horizontal posture and in multiple stages along a vertical direction with centers of the wafers 200 aligned with one another. That is, the boat 217 is configured to arrange the wafers 200 to be spaced apart from one another. The boat 217 is made of a heat-resistant material such as, for example, quartz, SiC or the like. Heat insulating plates 218 made of a heat-resistant material such as, for example, quartz, SiC or the like are supported in multiple stages at a lower portion of the boat 217. In the present disclosure, the expression of a numerical range such as “25 to 200” means that the lower limit and the upper limit are included in the range. Therefore, for example, “25 to 200” means “25 or more and 200 or less.” The same applies to other numerical ranges.

Inside the reaction tube 203, there is installed a temperature sensor 263 as a temperature detector. By independently regulating a state of electric power supply to each of the heaters 206a to 206e included in the heater 206 based on temperature information detected by the temperature sensor 263, a temperature in the process chamber 201 becomes a desired temperature distribution. The temperature sensor 263 is installed along an inner wall of the reaction tube 203.

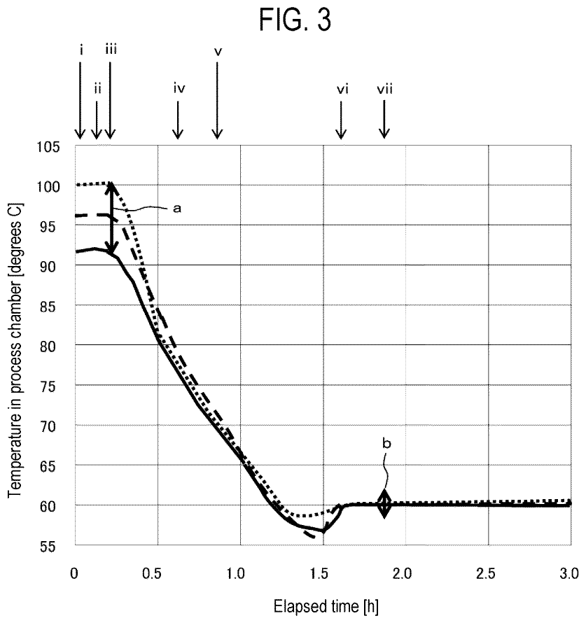

As shown in FIG. 3, the controller 121 as a control part (control means) is configured as a computer including a CPU (Central Processing Unit) 121a, a RAM (Random Access Memory) 121b, a memory 121c and an I/O port 121d. The RAM 121b, the memory 121c and the I/O port 121d are configured to be capable of exchanging data with the CPU 121a via an internal bus 121e. An input/output device 122 configured as, for example, a touch panel or the like is connected to the controller 121. In addition, an external memory 123 may be connected to the controller 121. The substrate processing apparatus may be configured to include one controller or a plurality of controllers. That is, control for performing a processing sequence to be described later may be performed using one controller or a plurality of controllers. Further, the plurality of controllers may be configured as a control system by being connected to each other via a wired or wireless communication network, and the control for performing the processing sequence to be described later may be performed by the entire control system. When the term “controller” is used herein, it may include one controller, a plurality of controllers, or a control system configured by a plurality of controllers.

The memory 121c is composed of, for example, a flash memory, a HDD (Hard Disk Drive), a SSD (Solid State Drive), or the like. The memory 121c stores, in a readable manner, control programs for controlling operations of the substrate processing apparatus, process recipes in which procedures and conditions, etc. of substrate processing to be described later are written, and the like. The process recipes are combinations that cause the controller 121 to have the substrate processing apparatus execute the respective procedures in the below-described substrate processing so as to obtain a predetermined result. The process recipes function as programs. Hereinafter, the process recipes, the control programs and the like are collectively and simply referred to as “programs.” Furthermore, the process recipes may also be simply referred to as “recipes.” When the term “programs” is used herein, it may mean a case of including the recipes, a case of including the control programs, or a case of including both. The RAM 121b is configured as a memory area (work area) in which programs, data, and the like read by the CPU 121a are temporarily held.

The I/O port 121d is connected to the MFCs, the valves, the pressure sensor, the APC valve 244, the vacuum pump 246, the heater 206, the temperature sensor 263, the supply side damper 264, the blower 270, the boat elevator 115, and the like.

The CPU 121a is configured to read a control program from the memory 121c and execute the control program, and is configured to read a recipe from the memory 121c in response to an input of an operation command and the like from the input/output device 122. The CPU 121a is configured to, according to the contents of the recipe thus read, control the flow rate regulating operation for various substances (various gases) by the MFCs, the opening/closing operations of the valves, the opening/closing operation of the APC valve 244, the pressure regulating operation by the APC valve 244 based on the pressure sensor, the start and stop of the vacuum pump 246, the temperature regulating operation of the heater 206 based on the temperature sensor 263, the opening/closing control for the supply side damper 264, the start, stop and the rotation speed regulation of the blower 270, the raising and lowering operation of the boat 217 by the boat elevator 115, and the like.

The controller 121 may be configured by installing, in the computer, the above-described programs recorded and stored in the external memory 123. The external memory 123 includes, for example, a magnetic disk such as a HDD or the like, an optical disk such as a CD or the like, a magneto-optical disk such as a MO or the like, a semiconductor memory such as a USB memory, a SSD, or the like, and so forth. The memory 121c and the external memory 123 are configured as a computer-readable recording media. Hereinafter, the memory 121c and the external memory 123 are collectively and simply referred to as “recording medium.” When the term “recording medium” is used herein, it may refer to a case of including the memory 121c, a case of including the external memory 123, or case of including both. The provision of the program to the computer may be performed by using a communication means such as the Internet or a dedicated line without having to use the external memory 123.

### (2) Substrate Processing Process

An example of substrate processing performed as a process of manufacturing a semiconductor device using the above-described substrate processing apparatus is described mainly with reference to FIG. 3. In the following description, the operation of each part included in the substrate processing apparatus is controlled by the controller 121.

The substrate processing according to the present embodiments includes:
(a) step A of regulating a temperature in a process chamber 201 configured to accommodate a plurality of wafers 200 so that a temperature distribution in an arrangement direction of the wafers 200 in the process chamber 201 becomes a first distribution in which at least a portion of an inside of the process chamber 201 becomes a first temperature;
(b) step B of loading the wafers 200 into the process chamber 201 in a state in which the temperature distribution in the arrangement direction of the wafers 200 in the process chamber 201 is the first distribution;
(c) step C of, after step B, regulating the temperature in the process chamber 201 so that the temperature distribution in the arrangement direction of the wafers 200 in the process chamber 201 becomes a second distribution in which at least a portion of the inside of the process chamber 201 becomes a second temperature different from the first temperature; and
(d) step D of, after step C, processing the wafers 200 in a state in which the temperature distribution in the arrangement direction of the wafers 200 in the process chamber 201 is the second distribution.

### Step A: First Temperature Regulating Step

In step A, the temperature in the process chamber 201 is regulated to a predetermined temperature.

A detailed description is given below with reference to FIG. 3. FIG. 3 shows the temperature in the process chamber 201 at a predetermined timing for each of the upper region, the central region, and the lower region. The vertical axis in FIG. 3 indicates the temperature in each region in the process chamber 201 in [degrees C.]. The horizontal axis in FIG. 3 indicates an elapsed time in [h]. The dotted line in FIG. 3 indicates the temperature at the lower region in the process chamber 201. The dashed line indicates the temperature at the central region in the process chamber 201. The solid line indicates the temperature at the upper region in the process chamber 201. The arrow i in the upper part of FIG. 3 indicates a time when the temperature in the process chamber 201 exhibits a predetermined distribution (first distribution) due to the temperature regulating in step A, and indicates a time when the substrate processing apparatus is in an idle state to be described later. The arrow ii indicates a time when the substrate processing apparatus is in a standby state to be described later. The arrow iii indicates a start time of step B to be described later. The arrow iv indicates a start time of a pressure regulating step to be described later. The arrows v and vi indicate a start time and an end time of a process chamber cooling process of step C to be described later. The arrow vii indicates a start time of step D to be described later.

In step A, while the substrate processing apparatus is in a waiting state (idle state) until its transitions to the standby state, the temperature in the process chamber 201 is regulated so that the temperature distribution in the arrangement direction of the wafers 200 in the process chamber 201 becomes the first distribution (see a in FIG. 3) in which at least a portion (e.g., the lower region) in the process chamber 201 becomes the first temperature (e.g., 100 degrees C.). More specifically, set temperatures of the heaters 206a to 206e are regulated to achieves the first distribution in which the temperatures in the upper region, the central region, and the lower region are, for example, 92 degrees C., 96 degrees C., and 100 degrees C. (see arrow i in FIG. 3). At this time, the state of power supply to the heater 206 is feedback-controlled based on the temperature information detected by the temperature sensor 263 so that the process chamber 201 achieves such a temperature distribution. By doing so, 100 degrees C., which is the temperature in the lower region, becomes a maximum temperature value (first temperature) in the first distribution, and 92 degrees C., which is the temperature in the upper region, becomes a minimum temperature value in the first distribution. In the present embodiments, for example, the first distribution possesses a first deviation, i.e., a temperature width of 100 degrees C.−92 degrees C.=8 degrees C. As the temperature in each region in the process chamber 201 regulated in this step and step C, the temperature detected by the temperature sensor 263 provided in each region may be used.

It is not necessary to keep all of the heaters 206a to 206e in an on state for an entire period of this step. During at least a portion of the period, at least one selected from the group of the heaters 206a to 206e may be turned off while the other heaters are turned on to regulate the temperature in the process chamber 201.

### Step B: Wafer Loading Step

Thereafter, when the substrate processing apparatus receives an instruction to execute step B and transitions to the standby state (see arrow ii in FIG. 3), the lower end opening of the manifold 209 is opened, and as shown in FIG. 1, the boat 217 supporting the plurality of wafers 200 is raised by the boat elevator 115 and loaded into the process chamber 201 (boat loading). In this state, the seal cap 219 seals the lower end of the manifold 209. In this way, the wafers 200 are loaded (provided) into the process chamber 201.

At this time, in the present embodiments, the wafers 200 are loaded into the process chamber 201 in a state in which the temperature distribution in the arrangement direction of the wafers 200 in the process chamber 201 is in the above-mentioned first distribution (see arrow iii in FIG. 3). In this step, the boat 217, which is disposed outside the substrate processing apparatus and possesses a lower temperature than the temperature in the process chamber 201 at a time of loading, is loaded into the substrate processing apparatus. Therefore, the temperature in the process chamber 201 drops to about 80 degrees C. (see FIG. 3).

### Step C: Second Temperature Regulating Step

When the substrate processing apparatus transitions to the standby state, temperature regulating in the process chamber 201 is started as a second temperature regulating step. Specifically, the set temperatures of the heaters 206a to 206e are regulated so that the temperature distribution in the arrangement direction of the wafers 200 in the process chamber 201 becomes the second distribution (target temperature distribution) (see b in FIG. 3) in which at least a portion (e.g., the lower region) in the process chamber 201 becomes a second temperature (e.g., 60 degrees C.), which is a target temperature. For example, the set temperatures of the heaters 206a to 206e are regulated so that the temperatures in the upper region, the central region, and the lower region become 60 degrees C. That is, in the present embodiments, maximum and minimum values of the temperature in the second distribution are 60 degrees C., and a second deviation (temperature width) of the second distribution is 0 degrees C. However, even when the set temperature of the heater 206 is regulated (changed) in this manner, the temperature in the process chamber 201 does not immediately drop, and the temperature during the standby state (approximately 100 degrees C.) is essentially maintained for at least a predetermined time until step B is started (see FIG. 3).

The temperature regulating by the heater 206 as the second temperature regulating step is continuously performed even after the start of step B until an end of step D, in accordance with the set temperature of the heater 206 that is regulated to allow the temperature distribution in the process chamber 201 to achieve the second distribution. A start timing of the second temperature regulating step is not limited to before the start of step B (the time of transition to the standby state), and may be simultaneous with the start of step B or any timing between an end of step B and a start of step D.

In the present embodiments, the second temperature regulating step further includes cooling the process chamber 201 by the process chamber cooler so as to bring the temperature distribution in the process chamber 201 closer to the second distribution (process chamber cooling step). Specifically, the cooling gas discharged by the blower 270 is circulated through a space between the reaction tube 203 and the outer wall 210 (an outer space of the process chamber 201) via the supply pipe 251 to lower the temperature in the process chamber 201. At this time, the flow rate of the cooling gas discharged by the blower 270 is regulated so as to bring the temperature in the process chamber 201 closer to the second distribution (see arrows v and vi in FIG. 3). The flow rate of the cooling gas is regulated by at least one selected from the group of regulating the opening state of the supply side damper 264 and regulating the rotation speed of the blower 270. The cooling gas supplied to between the reaction tube 203 and the outer wall 210 is exhausted via the exhaust pipe 254.

In the present embodiments, by using both temperature control using the heater 206 and temperature control using the blower 270 (cooling device) as the second temperature regulating step from the time of the arrow v to the time of the arrow vi, it is possible to shorten a time taken until the temperature converges to the second distribution when the first temperature is higher than the second temperature. In addition, since accuracy of the temperature control by the heater 206 may increase even in a low temperature region, it is possible to shorten the time taken until the temperature converges to the second distribution. This is because, in the low temperature region, it may be difficult to perform accurate temperature control by solely controlling the power of the heater 206. As in the present embodiments, by controlling the power of the heater 206 while cooling the heater 206, it is possible to control the temperature with a high precision via the control of the power of the heater 206 even in the low temperature region.

### Pressure Regulating Step

After step B is completed, the vacuum pump 246 performs vacuum-exhaust (decompression-exhaust) so that the pressure inside the process chamber 201, i.e., a space in which the wafer 200 exists, reaches a desired pressure (vacuum level) (see arrow iv in FIG. 3). At this time, the pressure inside the process chamber 201 is measured by the pressure sensor, and the APC valve 244 is feedback-controlled based on the measured pressure information. The exhaust of the inside of the process chamber 201 continues at least until the processing of the wafers 200 is started.

### Step D: Substrate Processing Step

After the temperature in the process chamber 201 is regulated to the second distribution in step C, the wafers 200 loaded into the process chamber 201 are processed. As an example, predetermined precursor gas, reaction gas, and inert gas are supplied to the wafers 200 in the process chamber 201 to form a desired film on the wafers 200.

That is, in the present embodiments, the wafers 200 are processed in a state in which the temperature distribution in the arrangement direction of the wafers 200 in the process chamber 201 is set to the second distribution.

### After-Purge and Atmospheric Pressure Recovery

After step D is completed, an inert gas as a purge gas is supplied into the process chamber 201 from the nozzle and is exhausted through the exhaust pipe 231. As a result, the inside of the process chamber 201 is purged, and gases, reaction by-products, and the like remaining in the process chamber 201 are removed from the inside of the process chamber 201 (after-purge). Thereafter, the atmosphere in the process chamber 201 is replaced with the inert gas (inert gas replacement), and the pressure in the process chamber 201 is returned to normal pressure (atmospheric pressure recovery).

### Boat Unloading and Wafer Discharge

Thereafter, the seal cap 219 is lowered by the boat elevator 115, and the lower end of the manifold 209 is opened. Then, the processed wafers 200 are unloaded from the lower end of the manifold 209 to the outside of the reaction tube 203 while being supported by the boat 217 (boat unloading). After the boat is unloaded, the lower end opening of the manifold 209 is sealed (shutter close). The processed wafers 200 are discharged from the boat 217 after they are unloaded to the outside of the reaction tube 203 (wafer discharge).

### Step A′: First Temperature Regulating Step

After the boat unloading and the shutter close, the substrate processing apparatus transitions to an idle state again, and the heater 206 is controlled to regulate the temperature distribution in the process chamber 201 to become the first distribution.

### (3) Effects of the Present Embodiments

According to the present embodiments, one or more of the following effects may be obtained.

(a) In step A, the temperature distribution in the process chamber 201 is regulated to the first temperature distribution different from the second distribution (target temperature distribution) used during performing step D, and in step B, the wafers 200 are loaded into the process chamber 201 in the state in which the temperature distribution is set to the first distribution. Furthermore, in step C, the temperature is regulated to the second temperature distribution, and in step D, the wafers 200 are processed in the state in which the temperature distribution is set to the second distribution. As a result, when the temperature distribution in the process chamber 201, which fluctuates due to the loading of the wafers 200 into the process chamber 201, is converged to the second distribution, which is the target temperature distribution, the time required for the convergence may be shortened, thus improving a throughput of the substrate processing. This is described below.

When step B is performed, the boat 217 of a low temperature waiting outside the process chamber 201 is loaded into the process chamber 201, so that the temperature in the process chamber 201 drops. At this time, the boat 217 is raised from an open end side of the reaction tube 203 to the closed end side, so that an upper portion of the boat 217 heated by the entire heaters, for example, in the order of the heaters 206e, 206d, 206c, and 206b, is disposed in the upper region. A central portion of the boat 217 heated by the three heaters, for example, in the order of the heaters 206e and 206d, is disposed in the central region. The lower portion of the boat 217 heated solely by the heater 206e or hardly heated by the heater 206 is disposed in the lower region. In this way, the portions of the boat 217 that are heated by the heater 206 for different times during the boat loading depending on the regions are disposed in the process chamber 201. As a result, the temperature in the process chamber 201 after the boat 217 is loaded tends to exhibit deviations (variations) depending on the regions. Specifically, the temperature is highest in the upper region, and the temperature decreases downward from the central region to the lower region. Furthermore, since the boat loading in step B is performed in the state in which the lower end opening of the manifold 209 is opened, a low-temperature air outside the substrate processing apparatus flows into the substrate processing apparatus, thereby lowering the temperature in the process chamber 201. The lower region close to the lower end opening of the manifold 209 is most susceptible to the influence of this temperature drop, and the influence becomes less noticeable upward from the central region to the upper region. In the lower region, the temperature drop begins immediately after the start of boat loading, and then the temperature drop begins in the order of the central region and the upper region. In other words, a manner of temperature change over time after the start of boat loading (i.e., characteristics of the temperature change) differs from region to region. Furthermore, the temperature drop is greatest in the lower region, and the temperature drop decreases upward from the central region to the upper region. This enhances the tendency that the temperature in the process chamber 201 varies from region to region when step B is performed. If a large variation in the temperature distribution in the process chamber 201 occurs when step B is performed, a time required to eliminate this variation, i.e., a time required for the temperature distribution in the process chamber 201 to converge to the second distribution (target temperature distribution) (convergence time), may become long. This causes a delay in the start of step D, which may reduce the throughput.

In the present embodiments, in consideration of the temperature variation in the process chamber 201 that occurs during the execution of step B, the temperature distribution in the process chamber 201 is regulated in step A to the first distribution different from the second distribution that is the target temperature distribution. This makes it possible to shorten a time required for the temperature distribution in step C to converge to the second distribution. As a result, the start of step D may be advanced, and a decrease in the throughput may be avoided.

(b) By making the first temperature of the first distribution in step A higher than the second temperature of the second distribution in step C, it is possible to facilitate the temperature regulating (temperature control) using the heater 206 and shorten the time required to converge to the second distribution (target temperature distribution). Furthermore, by maintaining the inside of the process chamber 201 at a high temperature before performing step B in which the wafers 200 are loaded, it is possible to remove moisture in the process chamber 201 and reduce the influence of moisture in the process chamber 201 when performing step D.

(c) By making the minimum temperature value in the first distribution higher than the maximum temperature value in the second distribution, it is possible to improve the controllability of the temperature regulating using the heater 206 in step A. This makes it easier to further shorten the time required for the temperature distribution in the process chamber 201 to converge to the second distribution.

(d) In step A, the heater 206 is controlled so that the first distribution exhibits the first deviation. In this manner, by giving, in advance, a predetermined deviation (temperature width) to the first distribution in step A, it is possible to reduce the temperature deviation (temperature variation from region to region) in the arrangement direction of the wafers 200 that occurs when the wafers 200 are loaded into the process chamber 201.

(e) In step C, the temperature in the process chamber 201 is regulated so that the second distribution becomes uniform (the second deviation is zero) in the arrangement direction of the wafers 200. In this manner, by reducing the temperature deviation (temperature variation) in the process chamber 201 that occurs when the wafers 200 are loaded into the process chamber 201, it is possible to shorten the convergence time when performing the temperature control to obtain the second distribution in which the second deviation is zero.

(f) The first distribution is set such that the time taken for the temperature distribution in the process chamber 201 to converge to the second distribution from the start of step B is shorter compared to a case where the temperature in the process chamber 201 is regulated so that the temperature distribution in the process chamber 201 becomes the second distribution in step A. This makes it possible to shorten the convergence time and therefore improve the throughput.

(g) The first distribution is set such that a maximum value of the deviation of the temperature distribution in the process chamber 201 occurring after step B is smaller than that in the case where the temperature in the process chamber 201 is regulated to allow the temperature distribution in the process chamber 201 to become the second distribution in step A. This makes it possible to shorten the convergence time, thereby improving the throughput.

(h) The first distribution is set according to the characteristics of the change in the temperature distribution in the process chamber 201 caused by the loading of the wafers 200 in step B. Specifically, as described above, the lower region (the opening side of the reaction tube 203) is most susceptible to the influence of the temperature drop in the process chamber 201 caused by the loading of the wafers 200, and the influence is less noticeable upward, i.e., toward the central region and the upper region (the closed end side of the reaction tube 203). Taking this characteristic into consideration, in the present embodiments, the first distribution is set to possess a deviation that cancels (compensates for) the temperature variation that occurs when the wafers 200 are loaded. In detail, the temperature of the lower region is set to the maximum value in the first distribution, and the temperature of the upper region is set to the minimum value in the first distribution (see FIG. 3). By doing so, the convergence time may be further shortened, thereby further improving the throughput.

(i) The temperature of the process chamber 201 is regulated by controlling the heater 206 that heats the process chamber 201 in step A and controlling the heater 206 and the blower 270 that cools the process chamber 201 in step C, thus ensuring the above-mentioned effects.

### (4) Modifications

The substrate processing in the present embodiments may be modified as shown in the following modifications. These modifications may be combined as desired. Unless otherwise specified, the processing procedure and processing condition in each step of each modification may be the same as the processing procedure and processing condition in each step of the substrate processing described above.

### Modification 1

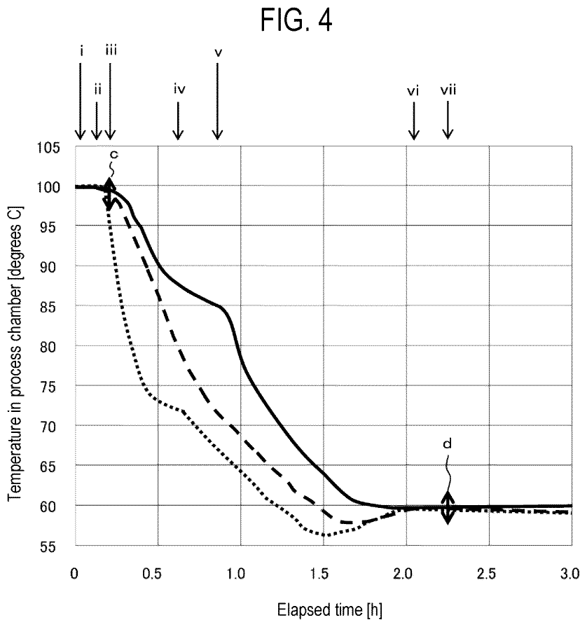

As shown in FIG. 4, in step A, it is not necessary to give a deviation (first deviation) to the first distribution (see c in FIG. 4) in advance to cancel the temperature deviation (temperature variation) that occurs when the wafers 200 are loaded. In other words, when the substrate processing apparatus is in the idle state, the temperature distribution in the process chamber 201 may be a first distribution in which the upper region, the central region, and the lower region are at the first temperature (e.g., about 100 degrees C.) (see arrow i in FIG. 4). In other words, when the substrate processing apparatus is in the idle state, the entire regions in the process chamber 201 may be heated uniformly so that they are at approximately the same temperature (see FIG. 4).

FIG. 4 shows the temperature in the process chamber 201 at a predetermined timing for each of the upper region, the central region, and the lower region. The vertical axis in FIG. 4 indicates the temperature in each region of the process chamber 201 in [degrees C.]. The horizontal axis in FIG. 4 indicates the elapsed time in [h]. The dotted line in FIG. 4 indicates the temperature at the lower region in the process chamber 201. The dashed line indicates the temperature at the central region in the process chamber 201. The solid line indicates the temperature at the upper region in the process chamber 201. The arrow i in the upper part of FIG. 4 indicates the time when the temperature in the process chamber 201 exhibits a predetermined distribution (first distribution) due to the temperature regulating in step A, and indicates the time when the substrate processing apparatus is in the idle state. The arrow ii indicates the time when the substrate processing apparatus is in the standby state. The arrow iii indicates the start time of step B. The arrow iv indicates the start time of the pressure regulating step. The arrows v and vi indicate the start time and end time of the process chamber cooling process of step C. The arrow vii indicates the start time of step D.

In this modification as well, by loading the wafers 200 at a temperature higher than a temperature range in the substrate processing step (see arrows iii and vii in FIG. 4), the temperature controllability is better than when loading the wafers 200 at the temperature range in the substrate processing process, and therefore the effect of shortening the convergence time is obtained.

### Modification 2

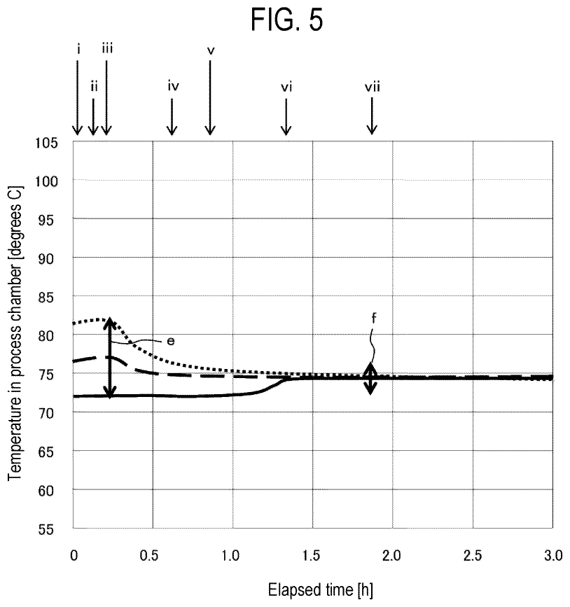

As shown in FIG. 5, in step A, the temperature in the process chamber 201 may be regulated to a first distribution (see e in FIG. 5) that is at a same temperature range (about 75 degrees C.) as the target temperature distribution (second distribution) (see f in FIG. 5). In other words, when the substrate processing apparatus is in the idle state, the temperature distribution in the process chamber 201 may be a first distribution in which the upper region, the central region, and the lower region are at relatively low temperatures similar to the temperature range (about 75 degrees C.) in the substrate processing step (see arrows i and vii in FIG. 5). In this way, when the substrate processing apparatus is in the idle state, the temperature distribution in the process chamber 201 may be a first distribution that is lower than that in the above-described embodiments. For example, the minimum value of the temperature in the first distribution may be lower than the maximum value of the temperature in the second distribution (see FIG. 5).

FIG. 5 shows the temperature in the process chamber 201 at a predetermined timing for each of the upper region, the central region, and the lower region. The vertical axis in FIG. 5 indicates the temperature in each region of the process chamber 201 in [degrees C.]. The horizontal axis in FIG. 5 indicates the elapsed time in [h]. The dotted line in FIG. 5 indicates the temperature at the lower region in the process chamber 201. The dashed line indicates the temperature at the central region in the process chamber 201. The solid line indicates the temperature at the upper region in the process chamber 201. The arrow i in the upper part of FIG. 5 indicates the time when the temperature in the process chamber 201 exhibits a predetermined distribution (first distribution) due to the temperature regulating in step A, and indicates the time when the substrate processing apparatus is in the idle state. The arrow ii indicates the time when the substrate processing apparatus is in the standby state. The arrow iii indicates the start time of step B. The arrow iv indicates the start time of the pressure regulating step. The arrows v and vi indicate the start time and end time of the process chamber cooling process of step C. The arrow vii indicates the start time of step D.

In this modification as well, a deviation that cancels out the temperature deviation (temperature variation) that occurs when the wafers 200 are loaded is given to the first distribution in advance in step A, and then the wafers 200 are loaded (see arrow i in FIG. 5), thereby achieving the effect of shortening the convergence time as compared to a case where the wafers 200 are loaded without giving this deviation to the first distribution.

### Other Embodiments of the Present Disclosure

The embodiments of the present disclosure are specifically described above. However, the present disclosure is not limited to the above-described embodiments, and various changes may be made without departing from the spirit of the present disclosure.

For example, in the above-described embodiments, the case where the temperature in the process chamber 201 is regulated using the heater 206 in step A is described as an example. However, the present disclosure is not limited to such embodiments. For example, the temperature in the process chamber 201 may be regulated by simultaneously using the heater 206 and the blower 270 during at least a portion of the period of step A. The same effects as those of the above-described embodiments may be obtained in this embodiment. Furthermore, in this embodiment, a sufficient temperature deviation (tilt controllable width) may be provided in advance even in a low temperature region. This is because temperature control in a temperature decreasing direction is not possible to be performed solely by power control of the heater 206. Therefore, especially in the low temperature region, it may be difficult to perform temperature control that locally creates a temperature difference. By simultaneously using the blower 270 as in this embodiment, the power control of the heater 206 is performed while cooling the reaction tube 203 (process chamber 201) and the heater 206. Therefore, the temperature control to locally create a temperature difference by the power control of the heater 206 may be easily performed even in the low temperature region, and a sufficient temperature deviation may be provided.

For example, in the above-described embodiments, the case where the heater 206 and the blower 270 are used simultaneously to regulate the temperature in the process chamber 201 during at least a portion of the period of step C is described as an example. However, the present disclosure is not limited to such embodiments. For example, the temperature in the process chamber 201 may be regulated using solely the blower 270 during at least a portion of the period of step C. That is, the power supply to the heater 206 may be stopped (turned off) during at least a portion of the period of step C. In this case, for example, the temperature control using the heater 206 may be started or resumed at a timing when a temperature of any region in the process chamber 201 drops to a predetermined temperature or lower. In this embodiment, the same effects as those of the above-described embodiments may be obtained.

For example, in the above-described embodiments, in step C, the case where the temperature in the process chamber 201 is regulated so that the second distribution is uniform (the second deviation is zero) in the arrangement direction of the wafers 200 is described as an example. However, the present disclosure is not limited to such embodiments. For example, the second distribution may possess a second deviation that is smaller than the first deviation other than zero. In this embodiment, the same effects as those of the above-described embodiments may be obtained.

Although not specifically described in the above-described embodiments, when the first temperature is set (controlled) to be higher than the second temperature, step E of increasing the temperature in the process chamber 201 after step D in a state in which the plurality of wafers 200 are accommodated in the process chamber 201, and step F of unloading the wafers 200 from the process chamber 201 after step E may be further performed. In this embodiment, the same effects as those of the above-described embodiments may be obtained. Furthermore, in this embodiment, the wafers 200 may be unloaded from the process chamber 201 after removing moisture generated during the processing of step D from the wafers 200 and the process chamber 201. In addition, a time required for increasing the temperature in the process chamber 201 after unloading the wafers 200 may be shortened.

For example, in the above-described embodiments, the case where cooling by the blower 270 is started after the inside of the process chamber 201 is vacuum-exhausted is described as an example. However, the present disclosure is not limited to such embodiments. For example, cooling by the blower 270 may be started before the vacuum-exhaust of the inside of the process chamber 201 is completed. In this embodiment, the same effects as those of the above-described embodiments may be obtained.

For example, in the above-described embodiments, the case where the temperature in the process chamber 201 is lowered by allowing the cooling gas taken in through the supply pipe 251 to circulate in an outer peripheral space of the process chamber 201 and then be discharged by the blower 270 is described as an example. However, the present disclosure is not limited to such embodiments. For example, the flow direction of the cooling gas may be reversed from that of the above-described embodiments. That is, the temperature in the process chamber 201 may be lowered by allowing the cooling gas taken in through the exhaust pipe 254 to circulate in the outer peripheral space of the process chamber 201 and then be discharged by a blower provided on the side of the supply pipe 251. In this embodiment, the same effects as those of the above-described embodiments may be obtained.

It is preferable that a recipe used for each process is prepared separately according to processing contents and are recorded and stored in the memory 121c via an electric communication line or an external memory 123. When starting each process, it is preferable that the CPU 121a suitably selects an appropriate recipe from a plurality of recipes recorded and stored in the memory 121c according to the processing contents. This makes it possible to form films of various film types, composition ratios, film qualities and film thicknesses with high reproducibility in one substrate processing apparatus. In addition, the burden on an operator may be reduced, enabling a quick start of each process while avoiding operation errors.

The above-described recipes are not limited to newly prepared ones, but may be prepared by, for example, changing existing recipes already installed in the substrate processing apparatus. In the case of changing the recipes, the recipes after the change may be installed in the substrate processing apparatus via an electric communication line or a recording medium in which the recipes are recorded. In addition, the input/output device 122 provided in the existing substrate processing apparatus may be operated to directly change the existing recipes already installed in the substrate processing apparatus.

In the above-described embodiments, there is described the example in which a film is formed by using a batch type substrate processing apparatus that processes a plurality of substrates at a time. The present disclosure is not limited to the above-described embodiments, but may be suitably applied to, for example, a case where a film is formed using a single-substrate type substrate processing apparatus that processes one or several substrates at a time. Furthermore, in the above-described embodiments, there is described the example in which a film is formed using a substrate processing apparatus with a hot-wall type process furnace. The present disclosure is not limited to the above-described embodiments, but may also be suitably applied to a case where a film is formed using a substrate processing apparatus with a cold-wall type process furnace.

Even when these substrate processing apparatuses are used, each process may be performed under the same processing procedures and processing conditions as those of the above-described embodiments and modifications. The same effects as those of the above-described embodiments and modifications may be obtained.

The above-described embodiments and modifications may be used in combination as appropriate. The processing procedure and processing conditions at this time may be, for example, the same as the processing procedures and processing conditions of the above-described embodiments and modifications.

According to the present disclosure in some embodiments, it is possible to shorten a time required for converging a temperature distribution in a process chamber, which fluctuates when loading a substrate into the process chamber, to a target temperature distribution, thereby improving a throughput of substrate processing.

While certain embodiments are described, these embodiments are presented by way of example, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

1. A substrate processing method, comprising:
(a) regulating a temperature in a process chamber configured to be capable of accommodating a plurality of substrates so that a temperature distribution in an arrangement direction of the plurality of substrates in the process chamber becomes a first distribution in which at least a portion of an inside of the process chamber becomes a first temperature;
(b) loading the plurality of substrates into the process chamber in a state in which the temperature distribution in the arrangement direction in the process chamber is the first distribution;
(c) after (b), regulating the temperature in the process chamber so that the temperature distribution in the arrangement direction in the process chamber becomes a second distribution in which at least a portion of the inside of the process chamber becomes a second temperature different from the first temperature; and
(d) after (c), processing the plurality of substrates in a state in which the temperature distribution in the arrangement direction in the process chamber is the second distribution.

2. The substrate processing method of claim 1, wherein the first temperature is higher than the second temperature.

3. The substrate processing method of claim 2, wherein a minimum temperature value in the first distribution is higher than a maximum temperature value in the second distribution.

4. The substrate processing method of claim 2, wherein a minimum temperature value in the first distribution is lower than a maximum temperature value in the second distribution.

5. The substrate processing method of claim 1, wherein in (a), the temperature in the process chamber is regulated so that the first distribution has a first deviation in the arrangement direction.

6. The substrate processing method of claim 5, wherein in (c), the temperature in the process chamber is regulated so that the second distribution has a second deviation smaller than the first deviation or is uniform in the arrangement direction.

7. The substrate processing method of claim 5, wherein the first distribution is set such that a time taken for the temperature distribution in the arrangement direction in the process chamber to converge to the second distribution from a start of (b) is shorter compared to a case where the temperature in the process chamber is regulated so that the temperature distribution in the arrangement direction in the process chamber becomes the second distribution in (a).

8. The substrate processing method of claim 5, wherein the first distribution is set such that a maximum value of a temperature deviation in the arrangement direction in the process chamber occurring after (b) is smaller compared to a case where the temperature in the process chamber is regulated so that the temperature distribution in the arrangement direction in the process chamber becomes the second distribution in (a).

9. The substrate processing method of claim 5, wherein the first distribution is set according to a characteristic of a change in the temperature distribution in the arrangement direction in the process chamber, which occurs when the plurality of substrates are loaded in (b).

10. The substrate processing method of claim 9, wherein a characteristic of a temperature change in the process chamber with respect to a lapse of time after starting the loading of the plurality of substrates, which occurs when the plurality of substrates are loaded in (b), differs depending on a position in the arrangement direction.

11. The substrate processing method of claim 1, wherein the first temperature is higher than the second temperature, and
wherein in (a) and (c), the temperature in the process chamber is regulated so that each of the first distribution and the second distribution becomes uniform in the arrangement direction.

12. The substrate processing method of claim 1, wherein in (b), the plurality of substrates are loaded along the arrangement direction from an opening side of a process container that defines the process chamber, and
wherein in the first distribution, a temperature on the opening side is higher than a temperature on a closed end side of the process container.

13. The substrate processing method of claim 1, wherein in (a) and (c), the temperature in the process chamber is regulated by controlling at least one selected from the group of a heater configured to heat the process chamber and a cooler configured to cool the process chamber.

14. The substrate processing method of claim 13, wherein during at least a portion of a period of (a), the temperature in the process chamber is regulated by simultaneously using the heater and the cooler.

15. The substrate processing method of claim 13, wherein during at least a portion of a period of (c), the temperature in the process chamber is regulated by simultaneously using the heater and the cooler.

16. The substrate processing method of claim 13, wherein in (a), at least one selected from the group of the heater and the cooler is controlled so that the temperature distribution in the arrangement direction in the process chamber is the first distribution at a start time of (b).

17. The substrate processing method of claim 1, wherein the first temperature is higher than the second temperature, and
wherein the substrate processing method further comprises:
(e) after (d), increasing the temperature in the process chamber in a state in which the plurality of substrates are accommodated in the process chamber; and
(f) after (e), unloading the plurality of substrates from the process chamber.

18. A method of manufacturing a semiconductor device, comprising the substrate processing method of claim 1.

19. A non-transitory computer-readable recording medium storing a program that causes, by a computer, a substrate processing apparatus to perform a process comprising:
(a) regulating a temperature in a process chamber configured to be capable of accommodating a plurality of substrates so that a temperature distribution in an arrangement direction of the plurality of substrates in the process chamber becomes a first distribution in which at least a portion of an inside of the process chamber becomes a first temperature;
(b) loading the plurality of substrates into the process chamber in a state in which the temperature distribution in the arrangement direction in the process chamber is the first distribution;
(c) after (b), regulating the temperature in the process chamber so that the temperature distribution in the arrangement direction in the process chamber becomes a second distribution in which at least a portion of the inside of the process chamber becomes a second temperature different from the first temperature; and
(d) after (c), processing the plurality of substrates in a state in which the temperature distribution in the arrangement direction in the process chamber is the second distribution.

20. A substrate processing apparatus, comprising:
a process chamber configured to be capable of accommodating a plurality of substrates;
a substrate transporter configured to load the plurality of substrates into the process chamber;
a heater configured to heat an inside of the process chamber; and
a controller configured to be capable of controlling the substrate transporter and the heater to perform a process including:
(a) regulating a temperature in the process chamber so that a temperature distribution in an arrangement direction of the plurality of substrates in the process chamber becomes a first distribution in which at least a portion of the inside of the process chamber becomes a first temperature;
(b) loading the plurality of substrates into the process chamber in a state in which the temperature distribution in the arrangement direction in the process chamber is the first distribution;
(c) after (b), regulating the temperature in the process chamber so that the temperature distribution in the arrangement direction in the process chamber becomes a second distribution in which at least a portion of the inside of the process chamber becomes a second temperature different from the first temperature; and
(d) after (c), processing the plurality of substrates in a state in which the temperature distribution in the arrangement direction in the process chamber is the second distribution.
